(19) United States
(12) Patent Application Publication
(10) Pub. No.: US 2004/0140821 A1
(43) Pub. Date: Jul. 22, 2004

(54) Test PCB and contactor for testing of electronic device

(76) Inventor: Chaeyoon Lee, Busan (KR)

Correspondence Address: JONES DAY, 222 EAST 41ST ST, NEW YORK, NY, 10017, US

(21) Appl. No.: 10/680,336

(22) Filed: Oct. 7, 2003

(30) Foreign Application Priority Data
Jan. 21, 2003 (KR) 2003-3875
May 7, 2003 (KR) 2003-28948

(51) Int. Cl. G01R 31/02

(52) U.S. Cl. 324/754

(57) ABSTRACT

A test contactor mounted to a test printed circuit board (PCB) for testing a microwave device is disclosed. The test contactor comprises: a conductive housing inserted into at least one fixing hole formed at the test PCB; a conductive spring mounted in the housing; and a conductive probe having a bottom and a tip, and contacted with one end of the conductive spring inside the housing by the bottom and with one of electrode pads of the DUT by the tip, wherein the tip of the conductive probe is projected outside the test PCB to come into contact with the electrode pads of the DUT when the test contactor is inserted into said at least one fixing hole of the test PCB.

### FIELD OF THE INVENTION

The present invention relates generally to a method and system for testing the performance of electronic devices and in particular, to a printed circuit board (PCB) and contactor for testing the performance of RF and microwave devices.

### BACKGROUND OF THE INVENTION

A process of fabrication of electronic devices is well known in the industry. In general, electronic components, such as resistors, inductors, capacitors, and transistors, are mounted on a printed circuit board (PCB), which is a dielectric plate having a plurality of fixing holes. The components are interconnected with each other by means of a bus, formed from conductive material on a PCB. Often, many components are integrated onto a PCB to result in a so called high-integrated micro-chip. By mounting a plurality of high-integrated micro-chips on a single PCB, an electronic device for a particular application is formed. The micro-chips and other electronic components are then combined into the final product.

Due to the complexity of the fabrication process and a wide range of possible problems, electronic devices are often meticulously tested before being assembled into the final product. The testing of a device may include self performance of various components constituting the device, testing signal transmission performance between each component and its PCB, testing whether the components are properly connected to function as a final device, and so on. To this end, three conventional testing methods for Radio Frequency (RF) and microwave devices are illustrated in FIGS. 1a through 1c.

As shown in FIG. 1a, the first testing method is performed after an elastic probe 120 made of an elastic material such as rubber is arranged between an electrode pad 112 of a device under test 110 and a PCB 130 on which the device is to be mounted. This is called an elastic body contacting mode. The elastic probe 120 is a component designed in such a manner that a plurality of wires are embedded in the elastic material, so that electrical conduction is generated between the electrode pad 112 of the device and at least one fixing hole of the PCB to which the electrode pad is to be connected.

In this manner, the elastic probe 120 is arranged between the device under test and the PCB. This state has the same conditions as those of the device assembled into the PCB. In this state, it is tested to determine whether or not the device implements the desired functions. If the device does not implement the desired functions, it is considered that the device itself may be abnormal in performance, or that the bus of the PCB may be injured, or the like. Then, the cause is found to fix the problem.

Here, the elastic probe 120 itself has elastic force. Thus, when a predetermined force is applied to the elastic probe 120 between the PCB and the device, the device 110 and the PCB 130 closely approach each other, thus providing electrical connection to each other.

In this case, the elastic probe can be worn out, so that its life may become shortened. Since elastic material is sensitive to temperature, the elastic probe is subject to a failure caused by heat and/or a shortage of the elastic force at a low temperature, so that it frequently fails to exert its own functions. Further, a measurement error is generated by an impedance value of the elastic material itself, so it is difficult to conduct a precise test.

FIG. 1b shows the second conventional testing method. In contrast with the first method, the second testing method is adapted to remove the elastic probe, and then to bring the electrode pad 112 of the device into direct contact with an electrical conductive portion 132 around the corresponding fixing hole 131 of the PCB 130. This is called a circuit board direct contacting mode. In other words, the device is positioned at the corresponding position of the PCB, and then the device and the PCB are pressed toward each other, so that the electrode pad of the device is adapted to come into contact with the PCB.

The second testing method can overcome a disadvantage of the first method through removal of the elastic probe. However, when the number of electrode pads of the device is increased, it is necessary to apply a very strong force in order to bring all electrode pads into contact with the PCB at the same time. In this case, there is a high possibility that the device or the PCB will break down. When a weak force is applied in order to avoid this breakdown, the electrical connection between the device and the PCB is not properly ensured, which is a disadvantage.

FIG. 1c shows the third testing method introduced in order to overcome the disadvantages of the first and second methods. The third testing method makes use of a contactor 150 comprising a non-conductive housing 151 having a plurality of through-holes 152 and a plurality of spring probes 153 which are inserted into each through-hole.

Each through-hole 152 is formed at a position corresponding to an electrical conductive portion 132 around a fixing hole 131 of the PCB 130. Both opposite ends of each through-hole are formed with an anti-release step 152′ for preventing each spring probe from escaping outside.

One end of the spring probe 153 facing toward the PCB is formed with a conductor which comes into contact with the electrical conductive portion 132 of the PCB, while the other end facing toward the device is formed with a conductor which comes into contact with the electrode pad 1 12 of the device.

When this test contactor is positioned at a correct position between the device and the PCB, the device and the PCB are electrically connected. In this state, performances of the device itself or the PCB are tested. Here, the correct position refers to one where the conductors on opposite sides of the spring probe are correctly positioned at the corresponding electrical conductive portion of the PCB and at the electrode pad of the device, respectively.

Although the third testing method overcomes the attrition problem of the first method as well as the disadvantage of the second method, it has its own limitations. In particular, due to the relatively large size of the contactor, it has high impedance, which degrades the accuracy of test measurements. To that end, testing conditions before and after assembly of the device are different, and therefore are not truly representative of the final conditions at which the device will operate.

Accordingly, there is a need for a PCB and test contactor for testing RF and microwave devices, which is capable of reducing attrition and damage and improving test efficiency and precision by ensuring effective contact with the tested device. There is also a need for a multi-layered test PCB having at least one additional substrate designed to carry out a precise test in consideration of losses related to fixing holes formed at the PCB.

### SUMMARY OF THE INVENTION

To satisfy aforementioned needs, in one aspect of the invention, there is provides a test contactor mounted to a test Printed Circuit Board (PCB) for testing a device under test (DUT). The test contactor preferably comprise a conductive housing inserted into at least one fixing hole formed at the test PCB, a conductive spring mounted in the housing, and a conductive probe having a bottom and a tip. The conductive prove is contacted with one end of the conductive spring inside the housing by the bottom and with one of electrode pads of the DUT by the tip. The tip of the conductive probe is projected outside the test PCB to come into contact with the electrode pads of the DUT when the test contactor is inserted into said at least one fixing hole of the test PCB.

In another aspect of the invention, there is provided a test PCB for testing a microwave device. The test PCB preferably comprises at least one fixing hole formed at a position equal to that of the test PCB on which the microwave device is to be mounted, a predetermined circuit pattern formed on at least one of both surfaces of the test PCB so as to test performances of the microwave device, and at least one test contactor mounted in the fixing hole and contacted with a corresponding electrode pad of the microwave device. The test contactor further comprises a conductive housing inserted into the fixing hole, a conductive spring mounted in the conductive housing, and a conductive probe having a tip and projected from the conductive housing to come into contact with the electrode pad of the microwave device.

Yet in another aspect of the invention, there is provided a method for fabricating a test PCB for testing a microwave device. In accordance with the method, first, at least one fixing hole is formed at a desired position of a dielectric substrate for the test PCB to coat a conductive material around the fixing hole. Then, a circuit pattern is formed on the dielectric substrate for testing the microwave device. Finally, a test contactor is inserted into the fixing hole. The test contactor preferably has a probe, a spring and a housing.

### BRIEF DESCRIPTION OF THE DRAWINGS

The above and other features and advantages of the present invention will be more apparent from the following detailed description taken in conjunction with the accompanying drawings, in which:

FIGS. 1a-1c are sectional views showing a construction of the conventional test apparatus for testing of microwave devices;

FIG. 2 is a sectional view showing a construction of a test contactor for testing a microwave device in accordance with a first embodiment of the present invention and a construction of a test PCB using the test contactor;

FIG. 3 is a sectional view showing a construction of a test contactor for testing a microwave device in accordance with a second embodiment of the present invention and a construction of a test PCB using the test contactor;

FIG. 4 is a sectional view showing a construction of a test contactor for testing a microwave device in accordance with a third embodiment of the present invention and a construction of a test PCB using the test contactor;

FIG. 5 is a sectional view showing a construction of a test PCB for testing a microwave device in accordance with a fourth embodiment of the present invention, in which the test PCB is capable of preventing a hole loss; and

FIGS. 6a-6d show procedures of fabricating a test PCB according to a fourth embodiment of the present invention.

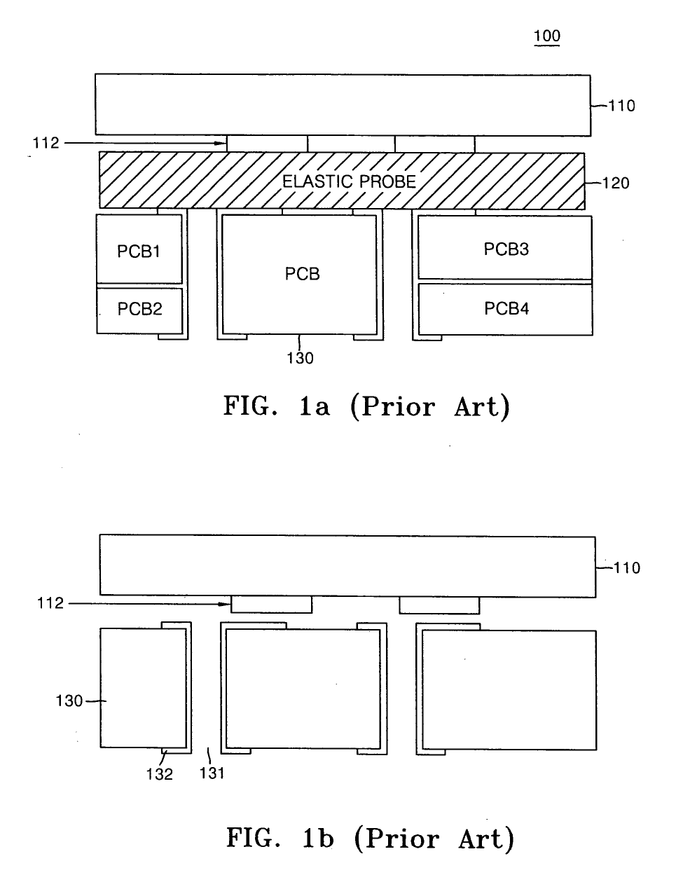

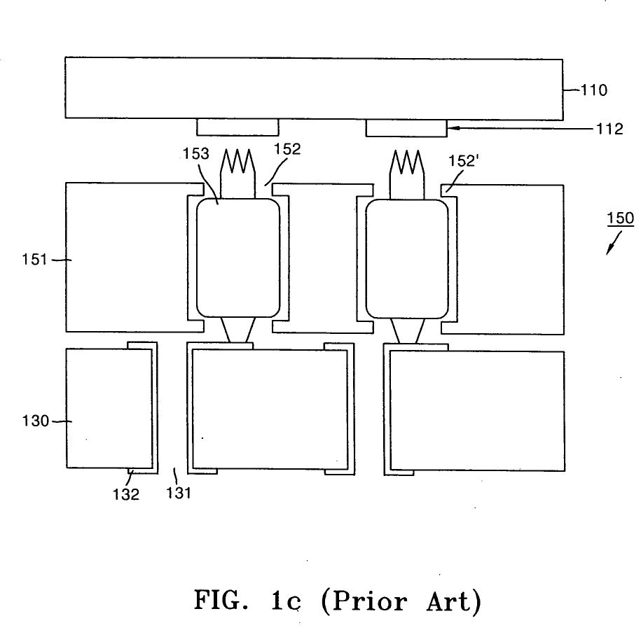

### DETAILED DESCRIPTION OF THE INVENTION

Hereinafter, a preferred embodiment of the present invention will be described with reference to the accompanying drawings. In the following description and drawings, the same reference numerals are used to designate the same or similar components, and so repetition of the description on the same or similar components will be omitted.

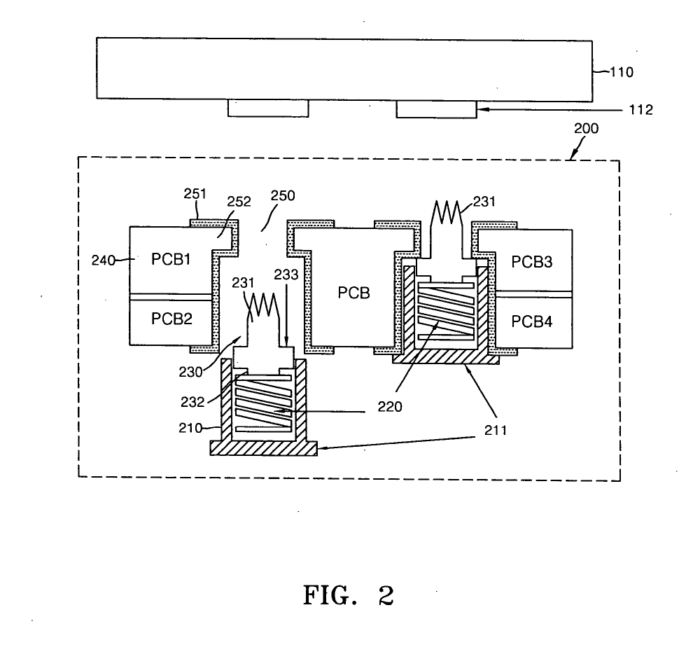

FIG. 2 is a sectional view showing a test contactor according to a first embodiment of the present invention and a test PCB 200 using the test contactor.

The PCB is formed with bus lines for signal transmission in a certain pattern, and with a plurality of holes for fixing devices such as electronic components, chips and so on. The holes are formed to pass through the PCB from its front surface to its rear surface, and are designed to transmit electrical signals of an electronic component or chip, which is mounted in any one of the holes, to another electronic component or chip, which is mounted in another of the holes, wherein these electronic components or chips are connected to the bus lines.

Each of the holes is coated with a conductive material, inserted by bridges of the electronic components or chips, and then filled with lead (Pb) molten during a soldering process. Thus, the holes are adapted to support the electronic components or chips and to allow the electrical signals to be transmitted to the bus lines. Herein, each such hole is called a “fixing hole”.

A microwave device employed to the present invention, as a small-scaled component having an operation frequency ranging from hundreds of MHz to tens of GHz, is exemplified by a filter group such as SAW filter, an oscillator group such as TCXO, VCXO and VCO, and an amplifier group such as a power amplifier. This microwave device may be used in Bluetooth, a radio frequency unit of a mobile phone, a wireless LAN, ETC and so forth, either by itself or in a module.

A microwave device (including a module type) needs to be tested to determine whether its functions are properly exerted before it is assembled with the PCB. This testing process is essential in producing semiconductors or electronic components.

A test contactor according to the first embodiment of the present invention comprises a cylindrical housing 210, a spring 220 inserted in the housing, and a probe 230. The housing 210 has an open upper end portion and a closed lower end portion and is formed with an insertion restraint step 211, which takes an annular flange shape and is projected along an outer circumference of the lower end portion. The probe 230 is inserted in the housing and comes into contact with one end (i.e., an upper end) of the spring. The probe 230 takes a cylindrical shape as a whole, and includes a tip 231 contacted with an electrode pad 112 of a device, a bottom 232 contacted with the upper end of the spring 220 inside the housing, and a locking projection 233 projected between the tip and the bottom in a radial outward direction.

In one embodiment of the present invention, the lower end portion of the housing 210 takes a completely closed shape. However, there is no limitation to such a shape. Therefore, as long as the housing 220 takes a shape capable of preventing the spring 220 and the probe 230 from escaping from inside the housing, it will do.

Further, the probe is illustrated as a cylindrical shape. However, there is no limitation to the shape. Thus, the probe may take another shape such as a square column, an elliptical cylinder and so on.

The PCB 240 consists of either a single layer or a plurality of layers. When the PCB 240 consists of a plurality of layers, each layer is formed with a predetermined circuit pattern.

Additionally, the PCB is formed with a plurality of fixing holes 250. Each of the holes 250 has its inner surface plated with a conductive material 251, which is also plated on the front and rear surfaces of the PCB surrounding each fixing hole. Further, on one end of the fixing hole 250 facing toward the device to be tested, a stopper 252 is formed, which is projected from the one end in a radial inward direction. As a result, each hole 250 has one end finished in a stepped shape.

The test PCB 200 is fabricated by inserting the test contactor constructed as mentioned above into the fixing hole of the PCB. The probe 230 may be inserted through the other end, a larger end, of the each fixing hole. The spring 220 is inserted to bring its one end into contact with the bottom 232 of the probe 230. Then, the housing 210 is inserted into and fixed to the fixing hole.

The state after the test contactor is inserted and fixed is shown in the right side of FIG. 2. Here, the tip 231 of the probe is projected outside the PCB and is adapted to elastically translate up and down by means of the spring. The locking projection 233 of the probe is locked at the stopper 252 of the fixing hole, so that the probe is prevented from escaping outside the fixing hole.

The housing 210 and the fixing hole 250 are firmly coupled to each other by means o an interference fit, soldering or the like. The insertion restraint step 211 of the housing 210 prevents the housing 210 from being completely inserted into the fixing hole.

When the foregoing test contactor is inserted in the fixing hole in order to test the device, the electrode pad 112 of the microwave device to be tested is positioned to come into contact with the probe 230 of the test contactor, and then the device and the PCB are pressed toward each other.

Since each probe 230 performs elastic movement, even a weak force allows all the probes to be contacted with the electrode pads of the device. When the device is contacted with the PCB, its performance is tested using a certain tester.

A description will now be made regarding a method for fabricating a test PCB 200 according to the first embodiment of the present invention. First, a test PCB 200 having a single layer or a plurality of layers is prepared, in which the test PCB 200 is identical to a real PCB to which a device is to be mounted and used. The test PCB 200 is formed with a plurality of fixing holes at each position at which each electrode pad of the device is to be contacted, in which each fixing hole is formed (with a stopper) in a stepped shape as shown in FIG. 2 and is plated with a conductive material such as copper in order to allow current to flow. Then, using a technique, such as an etching technique, equivalent or similar to a method for fabricating a PCB according to the prior art, a desired circuit pattern is formed on the test PCB 200 and plated with a noble metal such as gold in order to prevent oxidation of the pattern.

Subsequently, members of a test contactor, in particular, a probe, a spring and a housing are sequentially inserted and fixed in the stepped fixing hole.

It is preferred that a tip of the probe contacted with the electrode pad of the device takes a crown shape. However, the tip is not limited to the crown shape as shown, but can be modified according to a shape of the electrode pad of the device.

The spring is made from a conductive material, and causes the probe to perform elastic movement up and down, so that an uneven surface (in particular, of the electrode pad) of the device under test can be brought into contact with the fixing hole of the PCB.

The housing is also made from a conductive material, and functions not only to prevent both the probe and the spring from escaping from the fixing hole of the PCB, but also to transmit electrical signals, which are inputted through the tip of the probe from the device, to the PCB.

The housing may be inserted into and fixed in the fixing hole of the PCB by an interference fit, soldering or the like. However, the fixing means is not so limited.

The housing, the spring and the probe making up the test contactor according to the present invention are all made from a conductive material having good electrical conductivity, and preferably plated with a noble metal to prevent their erosion.

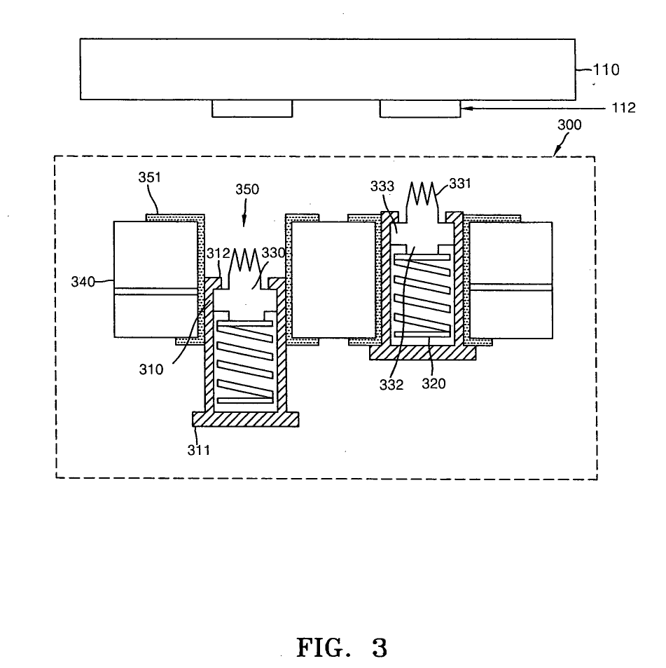

FIG. 3 is a sectional view showing a test contactor according to a second embodiment of the present invention and a test PCB 300 using the test contactor.

The test contactor according to the second embodiment of the present invention, like that of the first embodiment, includes a housing 310, a spring 320 and a probe 330.

Like the first embodiment, the housing 310 has an open upper end portion and a closed lower end portion, and is formed with an insertion restraint step 311, which is projected in an annular flange shape along an outer circumference of the lower end portion.

However, unlike the first embodiment, the open upper end portion of the housing 310 is formed with a probe stopper 312 projected in an annular flange shape in a radial inward direction. In addition, the housing 210 of the first embodiment is inserted up to the probe stopper 252 formed at the fixing hole 250, while the housing 310 of the second embodiment is lengthened and inserted up to a top end of a fixing hole 350.

Therefore, in the second embodiment, the fixing hole 350 of the PCB is formed as a typical through-hole without the probe stopper.

A probe 330 and a spring 320 according to the second embodiment are constructed equal to those of the first embodiment.

To be more specific, the probe 330 includes a tip 331 contacted with an electrode pad 112 of a device, a bottom 332 contacted with one end of the spring 320 inside the housing, and a locking projection 333 projected between the tip and the bottom in a radial outward direction.

Further, the other members excluding the fixing hole and the housing are constructed equal to those of the first embodiment.

That is, like the PCB 240 of the first embodiment, the PCB 340 may consist of a single layer or a plurality of layers. In the case of the plurality of layers, each layer is formed with a predetermined circuit pattern. The PCB is formed with a plurality of fixing holes 350. An inner surface of each fixing hole 350 is plated with a conductive material 351, which is also plated on front and rear surfaces of the PCB surrounding each fixing hole 350.

The test PCB 300 is fabricated by inserting the test contactor constructed as mentioned above into each fixing hole of the PCB. In this case, unlike the first embodiment where each member of the test contactor is inserted into the fixing hole, the test contactor, which has been previously assembled in a final product form, is inserted into and fixed in the fixing hole.

The state after the test contactor is inserted and fixed is shown in the right side of FIG. 3. Here, the tip 331 of the probe is projected outside the PCB and is adapted to elastically translate up and down by the spring 320. The locking projection 333 of the probe 330 is locked at the stopper 312 of the housing 310, so that the probe can be prevented from escaping outside the fixing hole.

The housing 310 and the fixing hole 350 are firmly coupled to each other by a fixing means, such as an interference fit, soldering or the like. The housing 310 is prevented from being excessively inserted into the fixing hole by insertion restraint step 311.

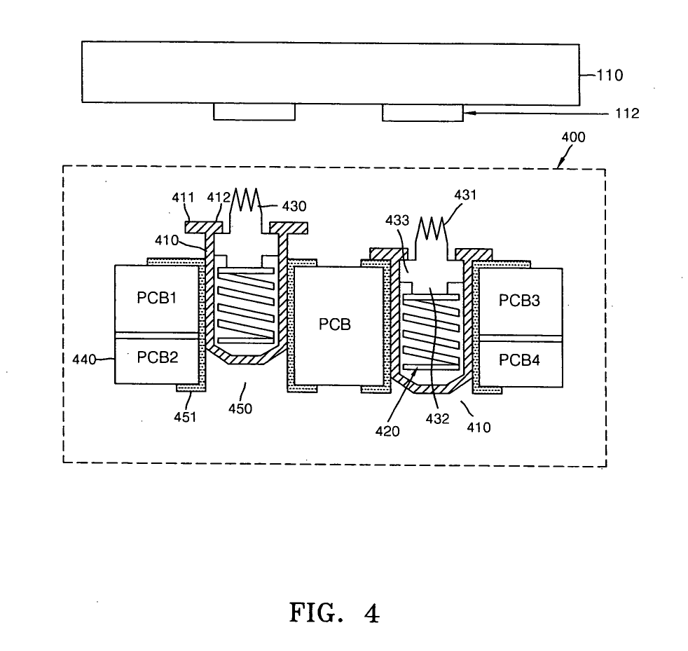

FIG. 4 is a sectional view showing a test contactor according to a third embodiment of the present invention and a test PCB 400 using the test contactor.

The test contactor according to the third embodiment of the present invention, similar to that of the first and second embodiments, includes a housing 410, along with a spring 420 and a probe 430, which are inserted into the housing.

The housing 410 has an open upper end portion and a closed lower end portion. However, unlike the first and second embodiments, the housing 410 is formed with an insertion restraint step 411, which is projected in an annular flange shape along an outer circumference of the open upper end portion.

The open upper end portion of the housing 410 is further formed with a stopper 412 projected in an annular flange shape in a radial inward direction.

Therefore, like the second embodiment, each fixing hole 450 of the PCB is formed in a typical through-hole form without the stopper 412 in the third embodiment.

A probe 330 and a spring 320 according to the third embodiment are constructed like those of the first and second embodiments, and thus their description will be omitted.

The test contactor, constructed as mentioned above, is inserted into and fixed in each fixing hole of the PCB in a manner like that of to the second embodiment, so that the test PCB 400 is fabricated as shown in FIG. 4.

The state after the test contactor is inserted and fixed is shown in the right side of FIG. 4. Here, the tip 431 of the probe is projected outside the PCB and is adapted to elastically translate up and down by the spring 420. Meanwhile, a locking projection 433 of the probe 430 is locked at the stopper 412 of the housing 410, so that the probe can be prevented from escaping outside the fixing hole.

The housing 410 and the fixing hole 450 are firmly coupled to each other by a fixing means, such as an interference fit, soldering or the like. The housing 410 is prevented from being excessively inserted into the fixing hole by its insertion restraint step 411.

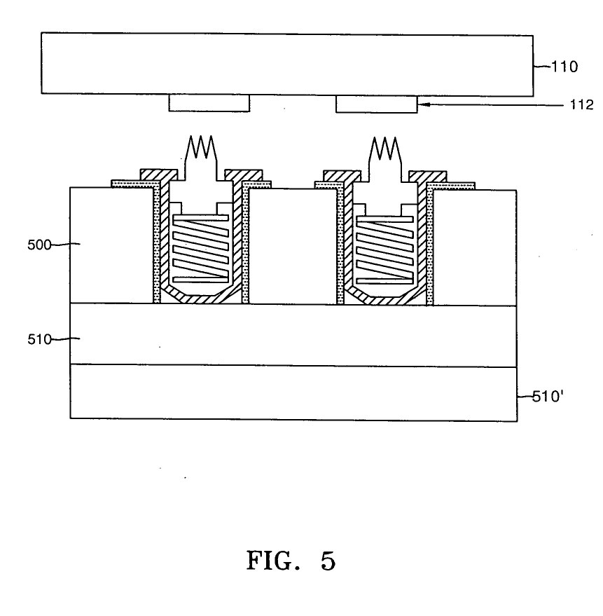

FIG. 5 is a sectional view showing a test PCB for testing a microwave device according to a fourth embodiment of the present invention, in which the test PCB is capable of preventing a hole loss.

When the device has an operation frequency of several GHz or more, a fixing hole formed to pass through the PCB functions as an element having a particular impedance. As a result, test conditions before the device is assembled are different from those after the device is assembled, so that a measurement error is generated. This phenomenon is called a “hole loss”.

The test PCB according to the fourth embodiment is implemented by bonding one or more additional substrates 510 and 510′ having a desired circuit to a rear surface of the test PCB 500 fabricated by a method of any one of the first to third embodiments, in which the rear surface the test PCB 500 is one spaced far from the device.

With use of the test PCB according to the fourth embodiment of the present invention, the fixing holes not only become shallower, but also have one end closed. Therefore, the foregoing hole loss can be prevented, and it is possible to reinforce a strength of the test PCB for testing the microwave device. Further, by containing a larger number of circuits within the same device, various performance tests can be carried out at the same time.

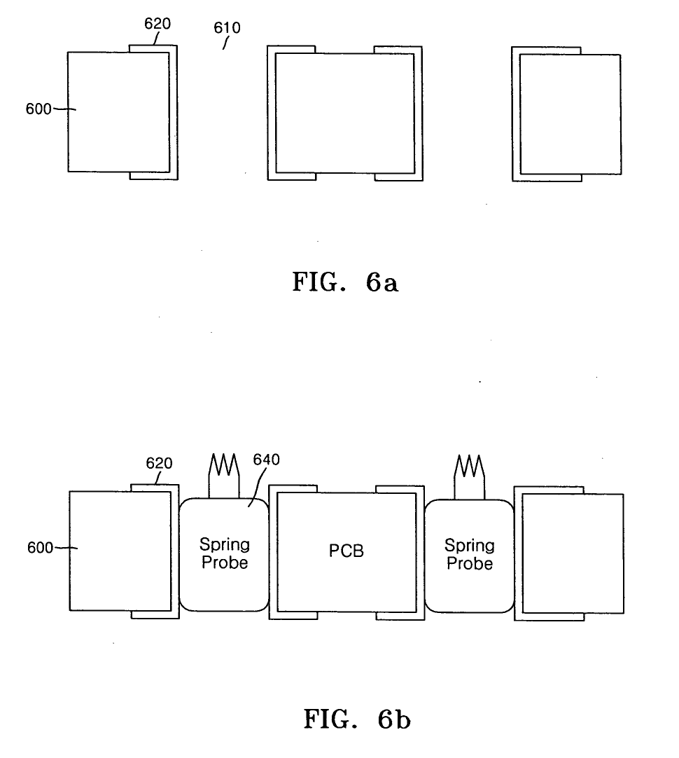

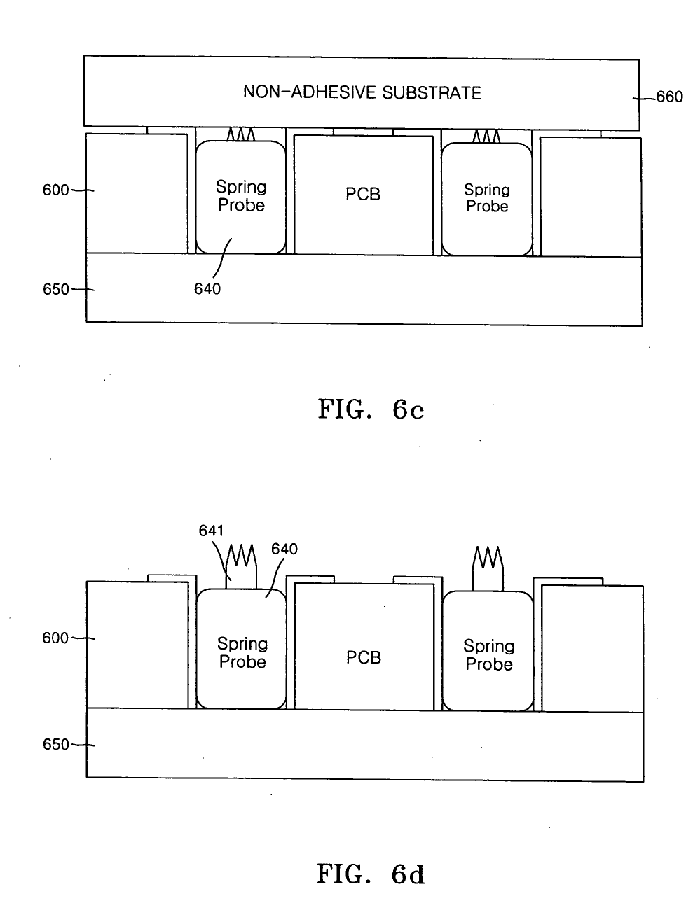

FIG. 6 shows procedures of fabricating a test PCB for testing a microwave device in accordance with the fourth embodiment.

First, a test PCB 600 is fabricated by a method of any one of the first to third embodiments.

To be more specific, as in FIG. 6a, the test PCB 600 is drilled to form at least one fixing hole 610. An inner surface of the fixing hole is covered with a conductive material 620, which is also plated on front and rear surfaces of the test PCB surrounding the fixing hole. Further, a circuit pattern, i.e. a bus line, which is identical to that of a real PCB to which a microwave device is to be used in reality, is formed on a surface of the test PCB. Of course, the circuit pattern or the bus line can be plated with a noble metal, etc. in order to prevent its oxidation.

Next, as shown in FIG. 6b, a proper test contactor 640 is inserted into and fixed in the fixing hole according to any one of the first to third embodiments. The fixing hole takes such a shape like that of the second or third embodiment. However, the fixing hole is not limited to such a shape, but it can be formed in a stepped shape, and thus it allows the test contactor as in FIG. 2 to be inserted inside.

The subsequent procedure is shown in FIG. 6c. An additional substrate 650 with a predetermined circuit pattern is disposed on the rear surface of the test PCB in order to face toward the device. A non-adhesive auxiliary substrate 660, which has the same structure as the additional substrate 650 and is not bonded by hot pressing, is disposed on the front surface of the test PCB (on the side of a tip of a probe). Then, three members, i.e., the additional substrate 650, the test PCB and the auxiliary substrate 660 are pressed at a high temperature. According to the present invention, at least one additional substrate 650 can be stacked. In this case, the procedure as in FIG. 6c is repeated at least once.

In FIG. 6d, the non-adhesive auxiliary substrate 660, which is spaced away from the bonded additional substrate 650, is removed. Thereby, the tip 641 of the probe of the test contactor 640 is exposed outside the test PCB.

According to this procedure, the additional substrate 650, which is not formed with the fixing hole, is bonded on the rear surface of the test PCB. As a result, the hole loss can be prevented, and it is possible to reinforce the strength of the test PCB for testing the microwave device. Further, the test PCB is provided with a large number of circuits.

According to the embodiments of the present invention, before the microwave device such as a microwave semiconductor IC is assembled with the PCB, the test contactor is disposed between the PCB and the device. Then, it is possible to test a performance of transmitting a signal between the PCB and the device, a performance of the device itself, etc.

As mentioned above, according to the present invention, with use of the test contactor and the test PCB using the test contactor, the microwave device can be tested in contact with the test PCB with ease and safety.

Particularly, it is possible to solve the problems in that the conventional elastic probe type test contactor has a shortened duration life due to an attrition of an elastic body or is vulnerable to heat due to inflammability, and that a measurement error is generated by an impedance value of the elastic probe itself.

Further, it is possible to solve problems, such as damage to the device, a contact failure of the device, as drawbacks generated in a direct contact mode in which the device comes into direct contact with the PCB.

Additionally, with use of the multiple layered test PCB including the additional substrate bonded on one surface of the PCB, the hole loss is prevented under the environment of a super high frequency, and it is possible to reinforce a strength of the test PCB for testing the microwave device. Further, the test PCB can be provided with a larger number of circuits.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A test contactor mounted to a test Printed Circuit Board (PCB) for testing a device under test (DUT), the test contactor comprising:
a. a conductive housing inserted into at least one fixing hole formed at the test PCB;
b. a conductive spring mounted in the housing; and
c. a conductive probe having a bottom and a tip, and contacted with one end of the conductive spring inside the housing by the bottom and with one of electrode pads of the DUT by the tip,
d. wherein the tip of the conductive probe is projected outside the test PCB to come into contact with the electrode pads of the DUT when the test contactor is inserted into said at least one fixing hole of the test PCB.

2. The test contactor as claimed in claim 1, wherein the conductive probe includes the tip contacted with the electrode pad of the DUT, the bottom contacted with the one end of the conductive spring inside the housing, and a locking projection projected between the tip and the bottom in a radial outward direction.

3. The test contactor as claimed in claim 2, wherein the conductive spring provides an elastic force to direct the conductive probe toward the DUT in the housing, both ends of the conductive spring being contacted with a bottom of the housing and the bottom of the conductive probe, respectively.

4. The test contactor as claimed in claim 3, wherein the housing comprises a hollow conductive shell shape in which one end thereof facing toward the DUT is opened and the other end is closed in whole or in part, at least one of two ends of the housing being formed with an insertion restraint step for preventing the housing from being released from the fixing hole of the test PCB or from being inserted into the fixing hole excessively.

5. The test contactor as claimed in claim 4, wherein the insertion restraint comprises an annular flange shape projected along an outer circumference of any one of the ends of the housing in a radial outward direction, and has a diameter larger than a diameter of the fixing hole.

6. The test contactor as claimed in claim 3, wherein the housing comprises a hollow conductive shell shape in which one end thereof facing toward the DUT is opened and the other end is closed in whole or in part, the one end of the housing being formed with a stopper projected in a radial inward direction in order to prevent a conductive probe from escaping from the housing by causing a locking projection of the conductive probe to be locked to the stopper.

7. A test Printed Circuit Board (PCB) for testing a microwave device, comprising:
a. at least one fixing hole formed at a position equal to that of the test PCB on which the microwave device is to be mounted;
b. a predetermined circuit pattern formed on at least one of both surfaces of the test PCB so as to test performances of the microwave device; and
c. at least one test contactor mounted in the fixing hole and contacted with a corresponding electrode pad of the microwave device,
d. wherein the test contactor comprises: a conductive housing inserted into the fixing hole; a conductive spring mounted in the conductive housing; and a conductive probe having a tip and projected from the conductive housing to come into contact with the electrode pad of the microwave device.

8. The test PCB as claimed in claim 7, wherein an inner surface of the fixing hole and a periphery of the fixing hole of the PCB are plated with a conductive material.

9. The test PCB as claimed in claim 7, wherein the circuit pattern of the test PCB is made of a conductive material and covered with a corrosion resistant metal in order to prevent corrosion.

10. The test PCB as claimed in claim 7, wherein at least one additional substrate having a predetermined circuit pattern is additionally bonded on one surface of the test PCB spaced away from the microwave device.

11. The test PCB as claimed in claim 7, wherein the conductive probe includes the tip contacted with the electrode pad of the microwave device, the bottom contacted with the one end of the conductive spring inside the conductive housing, and a locking projection projected between the tip and the bottom in a radial outward direction.

12. The test PCB as claimed in claim 11, wherein the conductive spring provides an elastic force to direct the conductive probe toward the microwave device in the conductive housing, both ends of the conductive spring being contacted with a bottom section of the conductive housing and the bottom of the conductive probe, respectively.

13. The test PCB as claimed in claim 12, wherein the conductive housing takes a hollow conductive shell shape in which one end thereof facing toward the microwave device is opened and the other end is closed in whole or in part, at least one of two ends of the conductive housing being formed with an insertion restraint step for preventing the conductive housing from being released from the fixing hole of the test PCB or from being inserted into the fixing hole excessively.

14. The test PCB as claimed in claim 13, wherein the insertion restraint step takes an annular flange shape projected along an outer circumference of any one of the ends of the conductive housing in a radial outward direction, and has a diameter larger than a diameter of the fixing hole.

15. The test PCB as claimed in claim 12, wherein the conductive housing takes a hollow conductive shell shape in which one end thereof facing toward the microwave device is opened and the other end is closed in whole or in part, the one end of the conductive housing being formed with a stopper projected in a radial inward direction in order to cause a locking projection of the conductive probe to be locked at the stopper, so that the conductive probe is prevented from escaping from the conductive housing.

16. The test PCB as claimed in claim 11, wherein an inner surface of the fixing hole and a surface of the test PCB surrounding the fixing hole are plated with a conductive material, one end of the fixing hole facing toward the microwave device being provided with a probe stopper, which is projected in a radial inward direction in order to allow the locking projection of the conductive probe to be locked.

17. A method for fabricating a test Printed Circuit Board (PCB) for testing a microwave device, comprising the steps of:
a. forming at least one fixing hole at a desired position of a dielectric substrate for the test PCB to coat a conductive material around the fixing hole;
b. forming a circuit pattern on the dielectric substrate, the circuit pattern being needed to perform testing; and
c. inserting a test contactor into the fixing hole, the test contactor having a probe, a spring and a housing.

18. The method as claimed in claim 17, further comprising a step of (d) bonding at least one additional substrate having a predetermined circuit pattern on one surface of the test PCB spaced away from the microwave device after the test PCB is fabricated by steps (a) to (c).

19. The method as claimed in claim 18, wherein step (d) comprises the sub-steps of:
d-1. arranging the additional substrate having the predetermined circuit pattern on one surface of the test PCB spaced away from the microwave device after the test PCB is fabricated by steps (a) to (c);
d-2. arranging an non-adhesive auxiliary substrate on the other surface of the test PCB opposite to the additional substrate to bond the additional substrate to the test PCB by hot pressing of the additional substrate, the test PCB and the auxiliary substrate; and
d-3. removing the auxiliary substrate from the test PCB.

20. The method as claimed in claim 17, wherein step (b) further comprises a step of coating a corrosion resistant metal on the circuit pattern in order to prevent corrosion.

21. The method as claimed in any one of claims 17 to 20, wherein:
a. the test contactor includes a conductive housing inserted into at least one fixing hole formed at the test PCB, a conductive spring mounted in the housing, and a conductive probe having a bottom and a tip and contacted with one end of the spring inside the housing by the bottom and with one of electrode pads of the microwave device by the tip; and
b. the tip of the probe is projected outside the test PCB to come into contact with the electrode pad of the microwave device when the test contactor is inserted into the fixing hole of the test PCB.

22. The method as claimed in claim 21, wherein the probe includes the tip contacted with the electrode pad of the microwave device, the bottom contacted with the one end of the spring inside the housing, and a locking projection projected between the tip and the bottom in a radial outward direction.

23. The method as claimed in claim 21, wherein the spring provides an elastic force to direct the probe toward the microwave device in the housing, both ends of the spring being contacted with a bottom of the housing and the bottom of the probe, respectively.

24. The method as claimed in claim 23, wherein the housing takes a hollow conductive shell shape in which one end thereof facing toward the microwave device is opened and the other end is closed in whole or in part, at least one of two ends of the housing being formed with an insertion restraint step for preventing the housing from being released from the fixing hole of the test PCB or from being inserted into the fixing hole excessively.

25. The method as claimed in claim 24, wherein the insertion restraint step takes an annular flange shape projected along an outer circumference of any one of the ends of the housing in a radial outward direction, and has a diameter larger than a diameter of the fixing hole.

26. The method as claimed in claim 23, wherein the housing takes a hollow conductive shell shape in which one end thereof facing toward the microwave device is opened and the other end is closed in whole or in part, the one end of the housing being formed with a stopper projected in a radial inward direction in order to cause a locking projection of the probe to be locked at the stopper, so that the probe is prevented from escaping from the housing.

27. The method as claimed in claim 22, wherein in step (a), one end of the fixing hole facing toward the microwave device is further formed with a probe stopper, which is projected in a radial inward direction in order to allow the locking projection of the probe to be locked.
